(19) United States
(12) Patent Application Publication
(10) Pub. No.: US 2025/0151529 A1
(43) Pub. Date: May 8, 2025

(54) OLED DEVICE, MANUFACTURING METHOD FOR OLED DEVICE AND DISPLAY PANEL

(71) Applicant: HKC CORPORATION LIMITED, SHENZHEN (CN)

(72) Inventors: Yao LI, SHENZHEN (CN); Junfeng XIE, SHENZHEN (CN)

(73) Assignee: HKC CORPORATION LIMITED, SHENZHEN (CN)

(21) Appl. No.: 18/937,053

(22) Filed: Nov. 5, 2024

(30) Foreign Application Priority Data
Nov. 7, 2023 (CN) 202311467582.X

(51) Int. Cl. H10K 59/122; H10K 59/12

(52) U.S. Cl. CPC H10K 59/122; H10K 59/1201

(57) ABSTRACT

An organic light-emitting diode (OLED) device, a manufacturing method for the OLED device, and a display panel are disclosed. The OLED device includes a substrate, a pixel anode disposed on a surface of the substrate, a plurality of gate-type column spacers disposed on the surface of the substrate on both sides of the pixel anode, an organic functional layer, and a pixel cathode covering a surface of the organic functional layer. Each of the plurality of gate-type column spacers includes a body column perpendicular to the substrate and an auxiliary column protruding the body column in a direction perpendicular to the body column. A recess is defined by the body columns and the auxiliary columns of any adjacent two of the plurality of gate-type column spacers. The organic functional layer is disposed in the recess defined by any adjacent two of the plurality of gate-type column spacers.

### CROSS-REFERENCE TO RELATED APPLICATIONS

This application claims priority to Chinese Patent Application No. 202311467582.X, filed on Nov. 7, 2023, in the National Intellectual Property Administration of China, the contents of which are herein incorporated by reference in their entireties.

### TECHNICAL FIELD

The present disclosure relates to the field of display panels, and in particular to an organic light-emitting diode (OLED) device, a manufacturing method for the OLED device, and a display panel.

### BACKGROUND

An OLED device, with the advantages of surface light source, cold light, energy saving, fast response, flexibility, ultra-thin, low cost, and etc., is becoming more and more mature in mass production. Typically, a light-emitting layer of the OLED device includes RGB light-emitting films and a patterning process is required to prepare the RGB light-emitting films.

An ink jet printing, as a non-contact patterning technology, is configured to a spray ink droplet onto a specified location of a substrate to realize a direct patterning. Compared to a vacuum evaporation technology of OLED preparation, which is a current commercially-mature application, the ink jet printing technology has unique advantages. That is, the ink jet printing technology may achieve an approximate 90% material utilization rate, which is a significant improvement compared to a 5%-20% material utilization rate in the evaporation technology, and is not limited by either equipment or a large-sized precise metal mask plate, which facilitates in realizing a large-sized display panel. Since neither an expensive vacuum evaporation equipment nor a precise mask plate is required, the ink jet printing technology not only saves materials but also reduces a preparation cost, and thus gradually becomes one of the most potential applications in the printing technology of OLED preparation.

A main challenge of the ink jet printing technology in terms of depositing an organic light-emitting layer and preparing a high-quality film is a “coffee ring” problem. That is, a deposition thickness of a solute at a center of a droplet is different from a deposition thickness of the solute at a periphery of the droplet, which results in an uneven film. As illustrated in FIG. 1, FIG. 1 is a schematic view of a formation of a “coffee ring” effect in the related art. In case of the droplet spreading and being pinned to the substrate, an evaporation rate of a solvent at the periphery is greater than an evaporation rate of the solvent at the center. In order to compensate a loss of the solvent at the periphery, a capillary flow from the center to the periphery is generated inside the droplet and carries the solute to the periphery so that the solute deposited on the substrate ultimately forms an uneven thin film that is thick at the periphery and thin at the center, i.e., the “coffee ring”. As a result, a film uniformity of each organic light-emitting layer is greatly affected, leading to a display distortion and reducing a luminous efficiency.

### SUMMARY OF THE DISCLOSURE

A first aspect of the present disclosure provides an OLED device including: a substrate, a pixel anode disposed on a surface of the substrate, a plurality of gate-type column spacers disposed on the surface of the substrate on both sides of the pixel anode, an organic functional layer, and a pixel cathode covering a surface of the organic functional layer. Each of the plurality of gate-type column spacers includes a body column perpendicular to the substrate and an auxiliary column protruding the body column in a direction perpendicular to the body column. A recess is defined by the body columns and the auxiliary columns of any adjacent two of the plurality of gate-type column spacers. The organic functional layer is disposed in the recess defined by any adjacent two of the plurality of gate-type column spacers.

A second aspect of the present disclosure provides a manufacturing method for the OLED device. The manufacturing method includes: providing a substrate, forming more than one pixel anode that are spaced apart from each other on the substrate, forming a plurality of gate-type column spacers on the substrate on both sides of each of the more than one pixel anode, depositing an organic functional layers in a recess defined by any adjacent two of the plurality of gate-type column spacers, and depositing a pixel cathode on a surface of the organic functional layer. Each of the plurality of gate-type column spacers includes a body column perpendicular to the substrate and an auxiliary column protruding the body column in a direction perpendicular to the body column. The recess is defined by any adjacent two of the plurality of gate-type column spacers.

A third aspect of the present disclosure provides a display panel that includes the OLED device according to any one of embodiments according to the first aspect above.

### BRIEF DESCRIPTION OF THE DRAWINGS

In order to illustrate the technical solutions in the embodiments of the present disclosure more clearly, the following is a brief introduction of the drawings associated with the description of the embodiments. It is obvious that the drawings described as follows are only for some embodiments of the present disclosure. For a person of ordinary skills in the art, other drawings may be obtained based on the following drawings without creative work.

FIG. 1 is a schematic view of a formation of a “coffee ring” effect in the related art.

FIG. 2 is a schematic structural view of an OLED device according to an embodiment of the present disclosure.

FIG. 3 is a schematic view of a deposition process of an organic functional layer according to an embodiment of the present disclosure.

FIG. 4 is a schematic structural view of a gate-type column spacer according to an embodiment of the present disclosure.

FIG. 5 is a flowchart of a manufacturing method for an OLED device according to an embodiment of the present disclosure.

FIG. 6 is a schematic view of preparing a gate-type column spacer using a nanoimprinting technology.

FIG. 7 is a schematic structural view of a display panel according to an embodiment of the present disclosure.

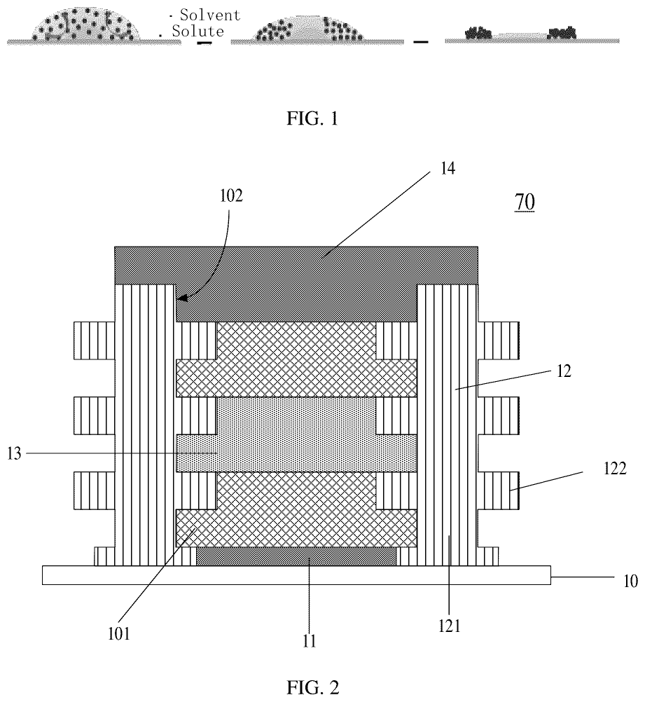

Reference numbers in the figures: 10, substrate; 11, pixel anode; 12, gate-type column spacer; 13, organic functional layer; 14, pixel cathode; 121, body column; 122, auxiliary column; 101, recess; 102, rectangular recess; 1221, first auxiliary column; 1222, second auxiliary column; Z, first direction; Y, second direction; 1011, recess opening; 1012, recess body; 60, printing film; 70, OLED device.

### DETAILED DESCRIPTION

The technical solutions in the embodiments of the present disclosure are clearly and thoroughly described below in conjunction with the drawings in the embodiments of the present disclosure. Obviously, the embodiments described are merely some embodiments, rather than all embodiments, of the present disclosure. Based on the described embodiments of the present disclosure, all other embodiments obtained by a person of ordinary skills in the art without creative work fall within the scope of protection of the present disclosure.

The terms used in the embodiments of the present disclosure are merely for the purpose of describing a particular embodiment and are not intended to limit the present disclosure. Any singular form, such as “a”, “said”, and “the”, used in the embodiments and the appended claims of the present disclosure may further refer to a plural form, unless otherwise clearly specified. The term “plurality” generally refers to at least two, but may not exclude a situation of at least one.

It is to be understood, the term “and/or” used herein is merely to describe an association relationship of the associated objects, which indicates that three types of relationships may exist. For example, A and/or B may refer to: A alone, both A and B, and B alone. In addition, the character “/” used herein generally indicates that the associated objects have an “or” relationship. The terms “first”, “second”, and etc., in the specification and claims of the present disclosure, as well as the drawings mentioned above, are used to distinguish similar objects, but are not necessarily be used to describe a particular order or sequence.

It is to be understood that, the terms “including”, “comprising” and any variations thereof used herein are intended to indicate a non-exclusive inclusion. In this way, each of a process, a method, an item or a device that includes a series of elements is not limited to the given series of elements, but may further include elements that are not explicitly listed or are inherent to the corresponding process, the corresponding method, the corresponding item or the corresponding device. Unless otherwise further limited, defining an element by the terms “including” or “comprising” may not exclude an existence of other identical elements in each of the process, the method, the item or the device that includes such element.

It is to be noted that, any directional indication (e.g., top, bottom, left, right, front, and back . . . ) in the embodiments of the present disclosure are only used to explain a relative positional relationship, movement, and etc., between components in a particular positioning (as illustrated in the drawing), and the directional indication may be changed correspondingly in response to the positioning being changed.

References to “embodiment” in the specification of the present disclosure indicate that a particular feature, structure, or characteristic described in conjunction with the embodiment may be included in at least one embodiment of the present disclosure. The “embodiment” appeared across the specification refers to neither necessarily an identical embodiment, nor a separate or alternative embodiment that is mutually exclusive with other embodiments. It can be understood by the person of ordinary skills in the art, both explicitly and implicitly, that the embodiments described herein may be combined with other embodiments.

Some embodiments of the present disclosure provide an OLED device. As illustrated in FIG. 2, FIG. 2 is a schematic structural view of an OLED device according to an embodiment of the present disclosure. The OLED device 70 includes a substrate 10, a pixel anode 11 disposed on the substrate 10, a plurality of gate-type column spacers 12 disposed on the substrate 10, an organic functional layer 13 disposed on the pixel anode 11, and a pixel cathode 14 disposed on the organic functional layer 13.

There may be more than one pixel anode 11. The more than one pixel anode 11 are spaced apart from each other on a surface of the substrate 10.

Each of the plurality of gate-type column spacers 12 is disposed on a corresponding space defined between any adjacent two pixel anodes 11 on the substrate 10. Each of the plurality of gate-type column spacers 12 includes a body column 121 perpendicular to the substrate 10 and an auxiliary column 122 protruding the body column 121 along a direction perpendicular to the body column 121. In some embodiments, each of the plurality of gate-type column spacers 12 may include more than one auxiliary column 122 and each auxiliary column 122 may protrude either side of the body column 121. A recess 101 is defined by the body columns 121 and the auxiliary columns 122 of any adjacent two of the plurality of gate-type column spacers 12 along a direction perpendicular to the substrate 10. In some embodiments, more than one recess 101 may be defined and the more than one recess 101 are stacked along the direction perpendicular to the substrate 10. The number of the recess 101 corresponds to the number of the auxiliary column 122, which may be one or more and is not limited herein.

The organic functional layer 13 is disposed in the recess 101 defined by any adjacent two of the plurality of gate-type column spacers 12. That is, the organic functional layer 13 is disposed on a surface of the pixel anode 11 between any adjacent two of the plurality of gate-type column spacers 12.

The pixel cathode 14 covers a surface of the organic functional layer 13 so that the organic functional layer 13 is disposed between the pixel cathode 14 and the pixel anode 11. In some embodiments, the auxiliary columns 122 of any adjacent two of the plurality of gate-type column spacers 12 are located in the middle of the corresponding body columns 121, i.e., is away from both ends of the corresponding body columns 121. The recess 101 is surrounded by the auxiliary columns 122 of any adjacent two of the plurality of gate-type column spacers 12 and a part of the body columns 121 that is located below auxiliary columns 122. In some embodiments, a rectangular recess 102 is partially surrounded by the auxiliary columns 122 of any adjacent two of the plurality of gate-type column spacers 12 and a part of the body columns 121 that is located above the auxiliary columns 122. The rectangular recess 102 may refer to an outer recess and the recess 101 may refer to an inner recess. The pixel cathode 14 is located in the rectangular recess 102. In some embodiments, each auxiliary column 122 of any adjacent two of the plurality of gate-type column spacers 12 may be located at an end of the corresponding body column 12 away from the substrate 10. In this case, the outer recess does not exist and the pixel cathode 14 protrudes a planar surface formed by the organic functional layer 13 and the plurality of gate-type column spacers 12. In some embodiments, the OLED device 70 may be a sub-pixel or a sub-pixel light-emitting unit disposed on a display panel. The display panel may include more than one OLED device 70. In some embodiments, the pixel cathode 14 covers the surface of the organic functional layer 13 and the surface of the plurality of gate-type column spacers 12, which allows the pixel cathodes 14 of any adjacent two OLED devices 70 to be connected to form an entire surface. In some embodiments, the pixel cathode 14 of each OLED device 70 may be isolated from one another, which is not limited herein. That is, the pixel cathode 14 is only required to either be disposed in the rectangular recess 102 or protrude the surface of the organic functional layer 13.

In some embodiments, the OLED device may include more than one organic functional layer 13. The number of the organic functional layer 13 is determined based on actual needs, which may be one or more and is not limited herein. The number of recess 101 may be determined based on the number of the organic functional layer 13 to be deposited therein. In other words, the number of the auxiliary column 122 of each of the plurality of gate-type column spacers 12 may be determined based on the number of the organic functional layer 13 to be deposited therein. The organic functional layer 13 may include a hole injection layer, a hole transport layer, an organic light-emitting layer, and so on.

In the related art, a OLED device is typically manufactured using an ink jet printing technology. To avoid a coffee ring effect occurs during a solidification of a solute of an organic functional layer due to using the ink jet printing technology, some embodiments of the present disclosure dispose the plurality of gate-type column spacers 12 to form the recess 101. The coffee ring effect occurs because an evaporation rate of a solvent at a periphery of a surface is greater than an evaporation rate of the solvent at a center of the surface. In order to compensate a loss of the solvent at the periphery, a capillary flow from the center to the periphery is generated inside the solvent and carries the solute to the periphery. In this way, the solute deposited on the substrate 10 ultimately forms an uneven thin film that is thick at the periphery and thin at the center.

In some embodiments, a hollow region defined between any adjacent two of the plurality of gate-type column spacers 12 is a light-emitting display area and is configured to deposit the organic functional layer 13. The plurality of gate-type column spacers 12 are located at a non-display area and are configured to isolate the organic functional layer 13 of each OLED device 70. In some embodiments, the organic functional layer 13 may be a light-emitting layer or a light-emitting functional layer. Each recess 101 defined by any adjacent two of the plurality of gate-type column spacers 12 is configured to deposit one organic functional layer 13. In response to the number of the organic functional layer 13 being changed, the number of the recess 101 may be changed correspondingly. The number of the organic functional layer 13 of each OLED device 70 may be different and is determined based on the number of the auxiliary column 122 of adjacent two gate-type column spacers 12.

In response to the ink jet printing of the organic functional layer 13 of each OLED device 70 being finished, the pixel cathode 14 located on the top part of the OLED device 70 may be manufactured using the ink jet printing or a photolithography technology. In some embodiments, a film layer of the pixel cathode 14 may be deposited on the surface of the plurality of gate-type column spacers 12 and the surface of the organic functional layer 13, which allows the pixel cathodes 14 of any adjacent two OLED devices 70 to be fully filled and connected to form a complete surface, thereby improving the uniformity of each pixel cathode 14 across the display panel.

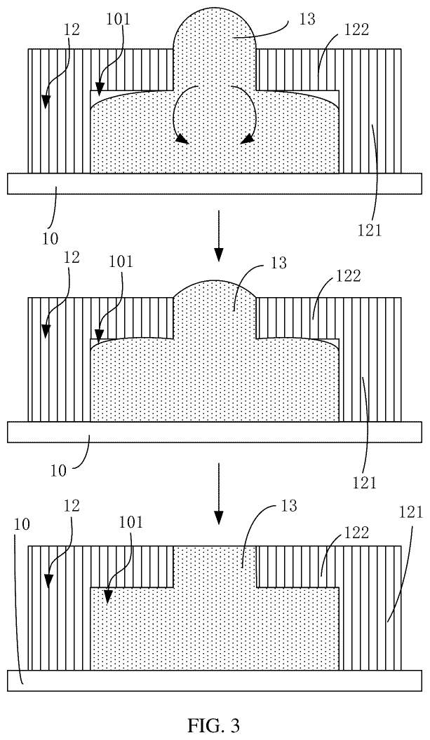

In some embodiments, the organic functional layer 13 is a droplet to be deposited in the recess 101 using the ink jet printing technology. FIG. 3 is a schematic view of a deposition process of an organic functional layer according to an embodiment of the present disclosure. FIG. 3 illustrates a change of a solute of a solvent of the organic functional layer 13 during the deposition process. The droplet spreads on the substrate 10 to be fully filled in the recess 101 and a small portion of the droplet protrudes the recess 101. Since the auxiliary columns 122 protruding the body columns 121 of any adjacent two gate-type column spacers 12 shield a periphery of the droplet, an evaporation rate of the solvent at the periphery of the organic functional layer 13 is less than an evaporation rate of the solvent at a center of the organic functional layer 13. In order to compensate a loss of the solvent at the center of the organic functional layer 13, a capillary flow from the periphery to the center is generated inside the droplet and carries a portion of the solute to the center of the organic functional layer 13. In this way, a capillary flow, generated by the “coffee ring” effect, from the center to the periphery inside the solvent is offset so that the solute deposited on the substrate 10 ultimately forms an even thin film, thereby greatly improving the solvent at the center and avoiding the common “coffee ring” effect. In some embodiments, the center of the organic functional layer 13 serves as a main light-emitting area and the periphery of the plurality of organic functional layers 13 may not serve as the main light-emitting area. Therefore, a luminous efficiency is greatly improved and a waste of light-emitting materials is avoided since the solvent at the center of the organic functional layer 13 is improved. In addition, a corresponding pixel opening area may be greatly increased through reducing a cross-sectional width of body columns 121 of any adjacent two of the plurality of gate-type column spacers 12.

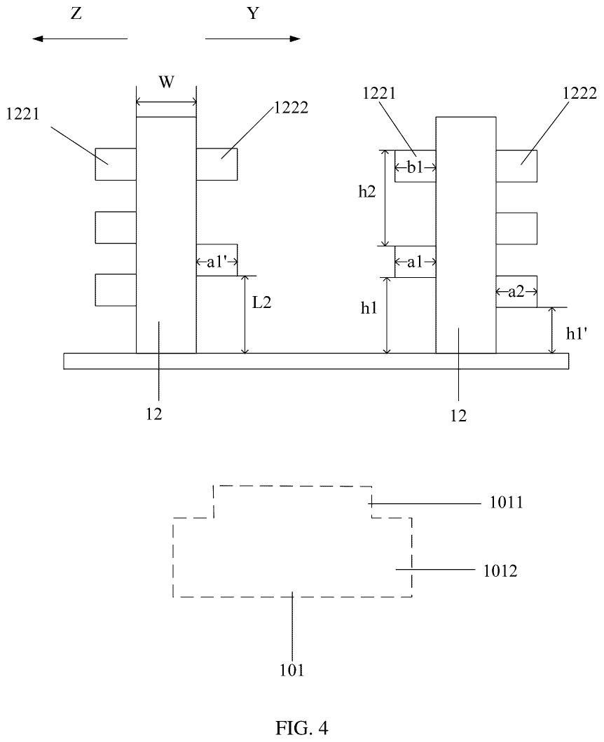

In some embodiments, FIG. 4 is a schematic structural view of a gate-type column spacer according to an embodiment of the present disclosure. As illustrated in FIG. 4, the auxiliary column 122 may be a first auxiliary column 1221 extending along a first direction Z perpendicular to the body column 121 or a second auxiliary column 1222 extending along a second direction Y perpendicular to the body column 121. The recess 101 is a recess that is narrow at the top and wide at the bottom. The recess 101 includes a recess opening 1011 and a recess body 1012. In some embodiments, the recess opening 1011 of the recess 101 is defined between the first auxiliary column 1221 of one of any adjacent two of the plurality of gate-type column spacers 12 and the second auxiliary column 1222 of the other one of the adjacent two of the plurality of gate-type column spacers 12 facing the first auxiliary column 1221. The recess body 1012 is defined between the body column 121 of one of any adjacent two of the plurality of gate-type column spacers 12 and the body column 121 of the other one of the adjacent two of the plurality of gate-type column spacers 12. A width of the recess opening 1011 is less than a width of the recess body 1012.

The first direction Z is a direction parallel to the substrate 10. The second direction Y is another direction parallel to the substrate 10 in opposite to the first direction Z. As illustrated in FIG. 4, the first direction Z is left and the second direction Y is right. The first direction Z and the second direction Y are not limited herein.

In some embodiments, a height of the first auxiliary column 1221 of one of any adjacent two of the plurality of gate-type column spacers 12 is equal to a height of the second auxiliary column 1222 of the other one of the adjacent two of the plurality of gate-type column spacers 12 facing the first auxiliary column 1221. In other words, a height of the first auxiliary column 1221 of one of the plurality of gate-type column spacers 12 is equal to a height of the second auxiliary column 1222 of adjacent one of the plurality of gate-type column spacers 12 in the first direction Z. A height of the second auxiliary column 1222 of one of the plurality of gate-type column spacers 12 is equal to a height of the first auxiliary column 1221 of adjacent one of the plurality of gate-type column spacers 12 in the second direction Y That is, the first auxiliary column 1221 of one of the plurality of gate-type column spacers 12 faces the second auxiliary column 1222 of left-adjacent one of the plurality of gate-type column spacers 12 and the second auxiliary column 1222 of one of the plurality of gate-type column spacers 12 faces the first auxiliary column 1221 of right-adjacent one of the plurality of gate-type column spacers 12. As illustrated in FIG. 4, a height of the first auxiliary column 1221 of one of the plurality of gate-type column spacers 12 is h1 and a height of the second auxiliary column 1222 of adjacent one of the plurality of gate-type column spacers 12 in the first direction Z is L2. h1 equals to L2. h1 is the height of the first auxiliary column 1221 on the right side of an OLED device 70 and L2 is the height of the second auxiliary column 1222 on the left side of the same OLED device 70. In some embodiments, each of the plurality of gate-type column spacers 12 may include more than one first auxiliary column 1221 and more than one second auxiliary column 1222. A height of each first auxiliary column 1221 (or a distance between any adjacent two first auxiliary columns 1221 in a vertical direction) of the same one of the plurality of gate-type column spacers 12 may be different, for example, h1 and h2 as illustrated in FIG. 4. Similarly, a height of each second auxiliary column 1222 (or a distance between any adjacent two second auxiliary columns 1222 in the vertical direction) of the same one of the plurality of gate-type column spacers 12 may be different. A height of the first auxiliary column 1221 or the second auxiliary column 1222 and a distance between any adjacent two first auxiliary columns 1221 or any adjacent two second auxiliary columns 1222 in the vertical direction may be determined based on a thickness of the organic functional layer 13 to be deposited.

In some embodiments, a length of the first auxiliary column 1221 of one of any adjacent two of the plurality of gate-type column spacers 12 is equal to a length of the second auxiliary column 1222 of the other one of the adjacent two of the plurality of gate-type column spacers 12 facing the first auxiliary column 1221. In some embodiments, a length of the first auxiliary column 1221 of one of the plurality of gate-type column spacers 12 is equal to a length of the second auxiliary column 1222 of adjacent one of the plurality of gate-type column spacers 12 in the first direction Z. A length of the second auxiliary column 1222 of one of the plurality of gate-type column spacers 12 is equal to the length of the first auxiliary column 1221 of adjacent one of the plurality of gate-type column spacers 12 in the second direction Y As illustrated in FIG. 4, a length of the first auxiliary column 1221 of one of the plurality of gate-type column spacers 12 is a1 and a length of the second auxiliary column 1222 of adjacent one of the plurality of gate-type column spacers 12 in the first direction Z is a1′. a1 equals to a1′. Therefore, a deposition rate on the left side of the organic functional layer 13 of an OLED device 70 is equal to a deposition rate on the right side of the organic functional layer of the same OLED device 70, which allows a more even film layer to be formed. As illustrated in FIG. 4, b1 and a1 may be either the same or different, which is not limited herein.

In some embodiments, a height of the first auxiliary column 1221 of one of the plurality of gate-type column spacers 12 may be not equal to a height of the second auxiliary column 1222 of the same one of the plurality of gate-type column spacers 12. A length of the first auxiliary column 1221 of one of the plurality of gate-type column spacers 12 may be not equal to a length of the second auxiliary column 1222 of the same one of the plurality of gate-type column spacers 12. In some embodiments, the height of the first auxiliary column 1221 of one of the plurality of gate-type column spacers 12 may be equal to the height of the second auxiliary column 1222 of the same one of the plurality of gate-type column spacers 12. The length of the first auxiliary column 1221 of one of the plurality of gate-type column spacers 12 may be equal to the length of the second auxiliary column 1222 of the same one of the plurality of gate-type column spacers 12. As illustrated in FIG. 4, h1 is not equal to h1′ and a1 is not equal to a2.

In some embodiments, each of the plurality of gate-type column spacers 12 includes the body column 121. A width of the body column 121 of each of the plurality of gate-type column spacers 12 may be different. The width W of the body column 121 may be determined based on an actual inter-pixel opening requirement, i.e., a width of the OLED device 70.

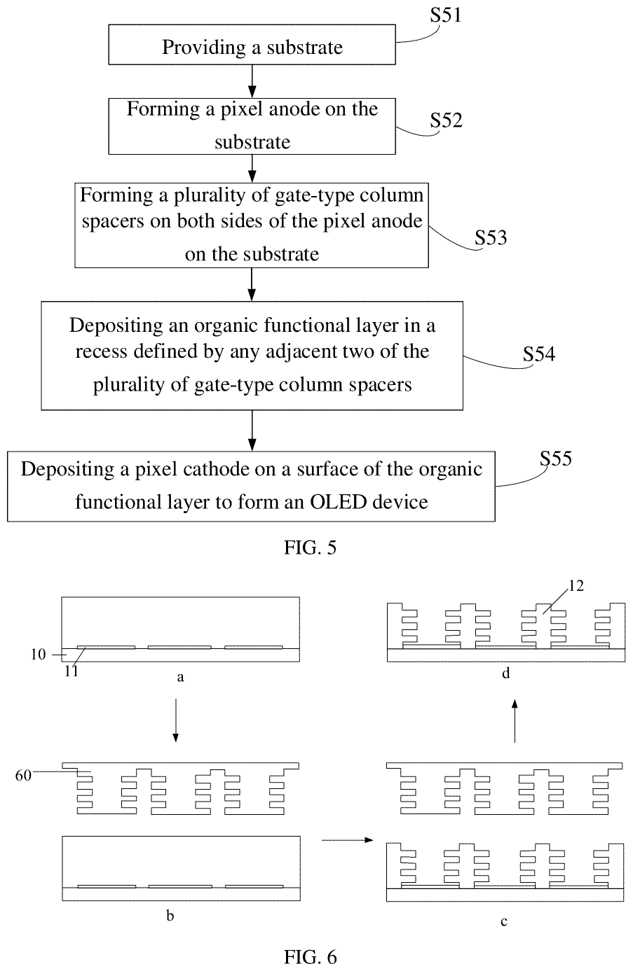

Some embodiments of the present disclosure provide a manufacturing method for an OLED device. As illustrated in FIG. 5, FIG. 5 is a flowchart of a manufacturing method for an OLED device according to an embodiment of the present disclosure. The manufacturing method includes the following operations.

At operation S51: providing a substrate.

The substrate 10 may be a glass substrate or a thin film transistor (TFT) substrate, which is not limited herein.

At operation S52: forming a pixel anode on the substrate.

There may be more than one pixel anode 11. The operation S52 further includes: forming more than one pixel anode that are spaced apart from each other on the substrate.

At operation S53: forming a plurality of gate-type column spacers on both sides of the pixel anode on the substrate.

The operation S53 further includes: forming a plurality of gate-type column spacers 12 on a corresponding space defined between any adjacent two pixel anodes 11 on the substrate 10.

Each of the plurality of gate-type column spacers 12 includes a body column 121 perpendicular to the substrate 10 and an auxiliary column 122 protruding the body column 121 along a direction perpendicular to the body column 121. In some embodiments, each of the plurality of gate-type column spacers 12 may include more than one auxiliary column 122 and each auxiliary column 122 may protrude either side of the body column 121. A recess 101 is defined by the body column 121 and the auxiliary column 122 of any adjacent two of the plurality of gate-type column spacers 12. The number of the auxiliary column 122 may be one or more. More than one recess 101 may be defined by the body column 121 and more than one auxiliary column 122, stacked along a direction perpendicular to the substrate 10.

A material of the plurality of gate-type column spacers 12 is a pixel defining layer. The operation S53 further includes: forming a pixel defining layer on a surface of the pixel anode 11 and a surface of the substrate 10 and imprinting the pixel defining layer located on the surface of the pixel anode 11 using a nanoimprinting technology. The pixel defining layer located on both sides of the pixel anode 11 remains unchanged to form the plurality of gate-type column spacers 12. FIG. 6 is a schematic view of preparing a gate-type column spacer using a nanoimprinting technology. As illustrated in part a of FIG. 6, the pixel defining layer covers the entire surface of both the pixel anode 11 and the substrate 10. As illustrated in part b of FIG. 6, a printing film 60 is applied to imprint the pixel defining layer. As illustrated in part c of FIG. 6, a demoulding process is performed after the imprinting. As illustrated in part d of FIG. 6, the plurality of gate-type column spacers 12, located on both sides of the pixel anode 11, are formed after the demoulding process.

At operation S54: depositing an organic functional layer in a recess defined by any adjacent two of the plurality of gate-type column spacers.

There may be more than one organic functional layer 13. The operation S54 further includes: depositing each of the more than one organic functional layer 13 in a corresponding one of the more than one recess 101 in sequence using the ink jet printing technology.

At operation S55: depositing a pixel cathode on a surface of the organic functional layer to form an OLED device.

The operation S55 further includes: forming a pixel cathode 14 on an entire surface of the organic functional layer 13 and an entire surface of the plurality of gate-type column spacers 12. In this way, the pixel cathode 14 of each sub-pixel or OLED device 70 is connected to form a complete surface.

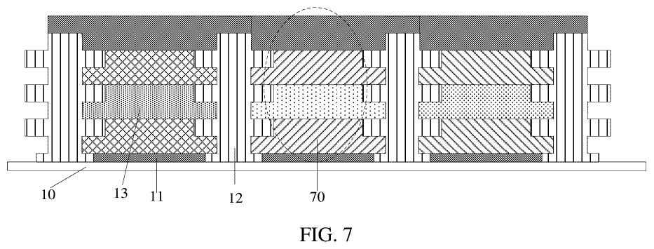

Some embodiments of the present disclosure further provide a display panel. FIG. 7 is a schematic structural view of a display panel according to an embodiment of the present disclosure. As illustrated in FIG. 7, the display panel includes more than one OLED device 70 according to any of the aforementioned embodiments. Any adjacent two OLED devices 70 share a single one of the plurality of gate-type column spacers 12. The pixel anode 11 and the organic functional layer 13 of each OLED device 70 are isolated by a corresponding one of the plurality of gate-type column spacers 12. Each OLED device 70 may emit light of a different color, i.e., red light, blue light, or green light, which is determined by the organic functional layer 13.

Some technical effects of the present disclosure may be the following. Any adjacent two of the plurality of gate-type column spacers 12 are disposed on both sides of the pixel anode 11, respectively. The recess 101 is defined between any adjacent two of the plurality of gate-type column spacers 12. In this way, each organic functional layer 13 is filled in the corresponding recess 101 defined between any adjacent two of the plurality of gate-type column spacers 12 during the ink jet printing. The common “coffee ring” effect may be avoided through controlling the evaporation rate of the solvent at the periphery, which greatly improves the uniformity across each organic functional layer 13 and enhances the luminous efficiency and a service life of the OLED device 70 in the display area. Moreover, the plurality of gate-type column spacers 12, in addition to improving the film layer uniformity, increasing inter-pixel opening area, and enhancing the luminous efficiency as mentioned above, may further serve as a slot configured to fix the film layer in case of the display screen being bent or folded, due to a concave structure of the plurality of gate-type column spacers 12.

The above only describes some embodiments of the present disclosure, and is not intended to limit the scope of protection of the present disclosure. Any equivalent structure or process alternations based on the specification of present disclosure and the drawings, and their direct or indirect application in other related technical fields, are all similarly included in the scope of protection of the present disclosure.

What is claimed is:

1. An organic light-emitting diode (OLED) device, comprising:
a substrate;
a pixel anode, disposed on a surface of the substrate;
a plurality of gate-type column spacers, disposed on the surface of the substrate on both sides of the pixel anode and each comprising a body column perpendicular to the substrate and an auxiliary column protruding the body column in a direction perpendicular to the body column, wherein a recess is defined by the body columns and the auxiliary columns of any adjacent two of the plurality of gate-type column spacers;
an organic functional layer, disposed in the recess defined by any adjacent two of the plurality of gate-type column spacers; and
a pixel cathode, covering a surface of the organic functional layer.

2. The OLED device according to claim 1, wherein each of the plurality of gate-type column spacers comprises more than one auxiliary column and more than one recess are defined by the body columns and the more than one auxiliary column of any adjacent two of the plurality of gate-type column spacers; the more than one recess are stacked along a direction perpendicular to the substrate;
the OLED device comprises more than one organic functional layer and each of the more than one organic functional layer is disposed in a corresponding one of the more than one recess in sequence.

3. The OLED device according to claim 1, wherein the auxiliary column is a first auxiliary column extending along a first direction perpendicular to the body column or a second auxiliary column extending along a second direction perpendicular to the body column;
a recess opening of the recess is defined between the first auxiliary column of one of any adjacent two of the plurality of gate-type column spacers and the second auxiliary column of the other one of the adjacent two of the plurality of gate-type column spacers facing the first auxiliary column;
a recess body of the recess is defined between the body column of one of any adjacent two of the plurality of gate-type column spacers and the body column of the other one of the adjacent two of the plurality of gate-type column spacers; and
a width of the recess opening is less than a width of the recess body, the first direction is a direction parallel to the substrate, and the second direction is another direction parallel to the substrate in opposite to the first direction.

4. The OLED device according to claim 3, wherein a height of the first auxiliary column of one of any adjacent two of the plurality of gate-type column spacers is equal to a height of the second auxiliary column of the other one of the adjacent two of the plurality of gate-type column spacers facing the first auxiliary column.

5. The OLED device according to claim 3, wherein a length of the first auxiliary column of any one of adjacent two of the plurality of gate-type column spacers is equal to a length of the second auxiliary column of the other one of the adjacent two of the plurality of gate-type column spacers facing the first auxiliary column.

6. The OLED device according to claim 3, wherein a height of the first auxiliary column of one of the plurality of gate-type column spacers is not equal to a height of the second auxiliary column of the same one of the plurality of gate-type column spacers;
a length of the first auxiliary column of one of the plurality of gate-type column spacers is not equal to a length of the second auxiliary column of the same one of the plurality of gate-type column spacers.

7. The OLED device according to claim 1, wherein the organic functional layer is located between the pixel anode and the pixel cathode.

8. The OLED device according to claim 1, wherein the recess is surrounded by the auxiliary columns of any adjacent two of the plurality of gate-type column spacers and a part of the body columns that is located below the auxiliary columns; and
a rectangular recess is partially surrounded by the auxiliary columns of any adjacent two of the plurality of gate-type column spacers and a part of the body columns that is located above the auxiliary columns.

9. The OLED device according to claim 1, wherein a material of the plurality of gate-type column spacers is same with a material of a pixel defining layer.

10. A manufacturing method for an organic light-emitting diode (OLED) device, comprising:
providing a substrate;
forming more than one pixel anode that are spaced apart from each other on the substrate;
forming a plurality of gate-type column spacers on the substrate on both sides of each of the more than one pixel anode, wherein each of the plurality of gate-type column spacers comprises a body column perpendicular to the substrate and an auxiliary column protruding the body column in a direction perpendicular to the body column; a recess is defined by any adjacent two of the plurality of gate-type column spacers;
depositing an organic functional layer in the recess defined by any adjacent two of the plurality of gate-type column spacers; and
depositing a pixel cathode on a surface of the organic functional layer.

11. The manufacturing method for an OLED device according to claim 10, wherein the forming a plurality of gate-type column spacers on the substrate on both sides of each of the more than one pixel anode comprises:
forming a pixel defining layer on a surface of the more than one pixel anode and a surface of the substrate; and
imprinting the pixel defining layer located on the surface of the more than one pixel anode using a nanoimprinting technology, wherein the pixel defining layer located on both sides of each of the more than one pixel anode remains unchanged to form a plurality of gate-type column spacers.

12. The manufacturing method for an OLED device according to claim 11, wherein the number of organic functional layer is more than one, the number of the recess is more than one, and the more than one recess are stacked along a direction perpendicular to the substrate; and
wherein the depositing an organic functional layer in the recess comprises:
depositing each of the more than one organic functional layer in a corresponding one of the more than one recess in sequence.

13. A display panel, comprising more than one organic light-emitting diode (OLED) device, wherein each of the more than one OLED device comprises:
a substrate;
a pixel anode, disposed on a surface of the substrate;
a plurality of gate-type column spacers, disposed on the surface of the substrate on both sides of the pixel anode and each comprising a body column perpendicular to the substrate and an auxiliary column protruding the body column in a direction perpendicular to the body column, wherein a recess is defined by the body columns and the auxiliary columns of any adjacent two of the plurality of gate-type column spacers;
an organic functional layer, disposed in the recess defined by any adjacent two of the plurality of gate-type column spacers; and
a pixel cathode, covering a surface of the organic functional layer.

14. The display panel according to claim 13, wherein each of the plurality of gate-type column spacers comprises more than one auxiliary column and more than one recess are defined by the body columns and the more than one auxiliary column of any adjacent two of the plurality of gate-type column spacers; the more than one recess are stacked along a direction perpendicular to the substrate;
the OLED device comprises more than one organic functional layer and each of the more than one organic functional layer is disposed in a corresponding one of the more than one recess in sequence.

15. The display panel according to claim 13, wherein the auxiliary column is a first auxiliary column extending along a first direction perpendicular to the body column or a second auxiliary column extending along a second direction perpendicular to the body column;
a recess opening of the recess is defined between the first auxiliary column of one of any adjacent two of the plurality of gate-type column spacers and the second auxiliary column of the other one of the adjacent two of the plurality of gate-type column spacers facing the first auxiliary column;
a recess body of the recess is defined between the body column of one of any adjacent two of the plurality of gate-type column spacers and the body column of the other one of the adjacent two of the plurality of gate-type column spacers; and
a width of the recess opening is less than a width of the recess body, the first direction is a direction parallel to the substrate, and the second direction is another direction parallel to the substrate in opposite to the first direction.

16. The display panel according to claim 15, wherein a height of the first auxiliary column of one of any adjacent two of the plurality of gate-type column spacers is equal to a height of the second auxiliary column of the other one of the adjacent two of the plurality of gate-type column spacers facing the first auxiliary column.

17. The display panel according to claim 15, wherein a length of the first auxiliary column of any one of adjacent two of the plurality of gate-type column spacers is equal to a length of the second auxiliary column of the other one of the adjacent two of the plurality of gate-type column spacers facing the first auxiliary column.

18. The display panel according to claim 15, wherein a height of the first auxiliary column of one of the plurality of gate-type column spacers is not equal to a height of the second auxiliary column of the same one of the plurality of gate-type column spacers;
a length of the first auxiliary column of one of the plurality of gate-type column spacers is not equal to a length of the second auxiliary column of the same one of the plurality of gate-type column spacers.

19. The display panel according to claim 13, wherein the organic functional layer is located between the pixel anode and the pixel cathode.

20. The display panel according to claim 13, wherein the recess is surrounded by the auxiliary columns of any adjacent two of the plurality of gate-type column spacers and a part of the body columns that is located below the auxiliary columns; and
a rectangular recess is partially surrounded by the auxiliary columns of any adjacent two of the plurality of gate-type column spacers and a part of the body columns that is located above the auxiliary columns.
